(19) United States
(12) Patent Application Publication
(10) Pub. No.: US 2026/0284794 A1
(43) Pub. Date: Sep. 24, 2026

(54) LASER PROCESSING APPARATUS, LASER PROCESSING SYSTEM, AND ELECTRONIC DEVICE MANUFACTURING METHOD

(71) Applicant: GIGAPHOTON INC., Tochigi (JP)

(72) Inventors: Yasufumi KAWASUJI, Tochigi (JP); Akira SUWA, Tochigi (JP); Daisuke MOMIYAMA, Tochigi (JP); Tomonari TANAKA, Tochigi (JP)

(73) Assignee: GIGAPHOTON INC., Tochigi (JP)

(21) Appl. No.: 19/467,275

(22) Filed: Feb. 2, 2026

(30) Foreign Application Priority Data
Mar. 11, 2025 (JP) 2025-038622

(51) Int. Cl. B23K 26/382; B23K 26/064; B23K 26/082; H10W 70/05

(52) U.S. Cl. CPC B23K 26/382; B23K 26/0643; B23K 26/0648; B23K 26/082; H10W 70/095

(57) ABSTRACT

A laser processing apparatus comprises: a first optical slit having an opening that extends in a second direction orthogonal to a first direction, a second optical slit disposed at a different position having an opening that extends in the first direction, an illumination optical system including a first relay optical system configured to transfer and reduce a beam image of the laser beam at a position of an output coupling mirror in the first direction and to illuminate the first optical slit, and a light condensing optical system configured to condense the laser beam in the second direction and to illuminate the second optical slit, and a projection optical system configured to form an image of the laser beam transmitted through the first and second optical slits on a workpiece surface to represent a shape of an overlapping portion of the first and second optical slit openings.

### CROSS-REFERENCE TO RELATED APPLICATIONS

The present application claims the benefit of Japanese Patent Application No. 2025-038622, filed on Mar. 11, 2025, the entire contents of which are hereby incorporated by reference.

### BACKGROUND

### 1. Technical Field

The present disclosure relates to a laser processing apparatus, a laser processing system, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248.0 nm and an ArF excimer laser apparatus that outputs a laser beam having a wavelength of about 193.4 nm are used.

In addition, excimer laser beams are sometimes used for direct processing of a polymer material and a glass material or the like, since a pulse width is several tens of ns and a wavelength is as short as about 248.0 nm and about 193.4 nm, respectively.

A chemical bond in a polymer material can be cut by an excimer laser beam having photon energy higher than bond energy. Therefore, it is known that non-heating processing of a polymer material is made possible by an excimer laser beam, and a processing shape becomes smooth.

Further, since glass, ceramics, and the like have a high absorptance to an excimer laser beam, it is known that even a material that is difficult to be processed by visible and infrared laser beams can be processed by an excimer laser beam.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: Japanese Unexamined Patent Application Publication No. 2008-060274

Patent Document 2: Japanese Unexamined Patent Application Publication No. 2009-134316

### SUMMARY

A laser processing apparatus according to one aspect of the present disclosure performs hole processing by irradiating a workpiece with a laser beam output from an output coupling mirror of a laser apparatus, and includes a first optical slit, a second optical slit, an illumination optical system, and a projection optical system. The first optical slit is disposed on an optical path of the laser beam and has an opening that extends in a second direction orthogonal to a first direction. The second optical slit is disposed at a position different from the first optical slit on the optical path of the laser beam and has an opening that extends in the first direction. The illumination optical system includes a first relay optical system configured to transfer and reduce a beam image of the laser beam at a position of the output coupling mirror in the first direction and to illuminate the first optical slit, and a light condensing optical system configured to condense the laser beam in the second direction and to illuminate the second optical slit. The projection optical system is configured to form an image of the laser beam transmitted through the first optical slit and the second optical slit on a surface of the workpiece to represent a shape of an overlapping portion of the opening of the first optical slit and the opening of the second optical slit.

A laser processing apparatus according to one aspect of the present disclosure performs hole processing by irradiating a workpiece with a laser beam output from an output coupling mirror of a laser apparatus, and includes a first optical slit, a second optical slit, an illumination optical system, and a projection optical system. The first optical slit is disposed on an optical path of the laser beam and has an opening that extends in a second direction orthogonal to a first direction. The second optical slit is disposed at a position different from the first optical slit on the optical path of the laser beam and has an opening that extends in the first direction. The illumination optical system includes a first relay optical system configured to transfer and reduce a beam image of the laser beam at a position of the output coupling mirror in the first direction and to illuminate the first optical slit, and a second relay optical system configured to transfer and reduce the beam image of the laser beam at the position of the output coupling mirror in the second direction and to illuminate the second optical slit. The projection optical system is configured to form an image of the laser beam transmitted through the first optical slit and the second optical slit on a surface of the workpiece to represent a shape of an overlapping portion of the opening of the first optical slit and the opening of the second optical slit.

An electronic device manufacturing method according to one aspect of the present disclosure includes forming a plurality of through-holes on a glass substrate as a workpiece by a laser processing apparatus, coupling and electrically connecting an interposer including the glass substrate and conductors provided in the respective through-holes and an integrated circuit chip to each other, and coupling and electrically connecting the interposer and a circuit board to each other. The laser processing apparatus performs hole processing by irradiating the workpiece with a laser beam output from an output coupling mirror of a laser apparatus, and includes a first optical slit disposed on an optical path of the laser beam and having an opening that extends in a second direction orthogonal to a first direction, a second optical slit disposed at a position different from the first optical slit on the optical path of the laser beam and having an opening that extends in the first direction, an illumination optical system including a first relay optical system configured to transfer and reduce a beam image of the laser beam at a position of the output coupling mirror in the first direction and to illuminate the first optical slit, and a second relay optical system configured to transfer and reduce the beam image of the laser beam at the position of the output coupling mirror in the second direction and to illuminate the second optical slit, and a projection optical system configured to form an image of the laser beam transmitted through the first optical slit and the second optical slit on a surface of the workpiece to represent a shape of an overlapping portion of the opening of the first optical slit and the opening of the second optical slit.

### BRIEF DESCRIPTION OF THE DRAWINGS

Some embodiments of the present disclosure will be described below, by way of example only, with reference to the accompanying drawings.

FIG. 1 is a diagram schematically illustrating a configuration of a laser processing system according to a comparative example.

FIG. 2 is a diagram schematically illustrating a configuration of a first optical slit.

FIG. 3 is a diagram schematically illustrating a configuration of a second optical slit.

FIG. 4 is a diagram schematically illustrating a configuration of a laser apparatus.

FIG. 5 is a diagram schematically illustrating a beam shape of a laser beam cut on a VH plane along a line A-A illustrated in FIG. 4.

FIG. 6 is a diagram schematically illustrating a shape of an image formed on a surface of a workpiece.

FIG. 7 is a diagram schematically illustrating a configuration of a laser processing system according to a first embodiment.

FIG. 8 is a diagram illustrating a specific configuration example of a first relay optical system and a second light condensing optical system.

FIG. 9 is a diagram schematically illustrating a configuration of a laser processing system according to a first modification.

FIG. 10 is a diagram schematically illustrating a configuration of a laser processing system according to a second modification.

FIG. 11 is a diagram schematically illustrating a configuration of a laser processing system according to a second embodiment.

FIG. 12 is a diagram schematically illustrating a configuration of a laser processing system according to a first modification.

FIG. 13 is a diagram schematically illustrating a configuration of a laser processing system according to a second modification.

FIG. 14 is a diagram schematically illustrating a configuration of an optical axis monitor.

FIG. 15 is a diagram schematically illustrating a configuration of an electronic device.

FIG. 16 is a diagram illustrating an electronic device manufacturing method.

### DESCRIPTION OF EMBODIMENTS

<Contents>
   1. Comparative Example
      1.1 Configuration
      1.2 Operation
      1.3 Problem
   2. First Embodiment
      2.1 Configuration
      2.2 Operation
      2.3 Effect
   3. Modifications of First Embodiment
      3.1 First Modification
         3.1.1 Configuration
         3.1.2 Operation
         3.1.3 Effect
      3.2 Second Modification
         3.2.1 Configuration
         3.2.2 Operation
         3.2.3 Effect
   4. Second Embodiment
      4.1 Configuration
      4.2 Operation
      4.3 Effect
   5. Modifications of Second Embodiment
      5.1 First Modification
      5.2 Second Modification
   6. Optical Axis Monitor
   7. Configuration Example of Laser Processing Processor

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Comparative Example

### 1.1 Configuration

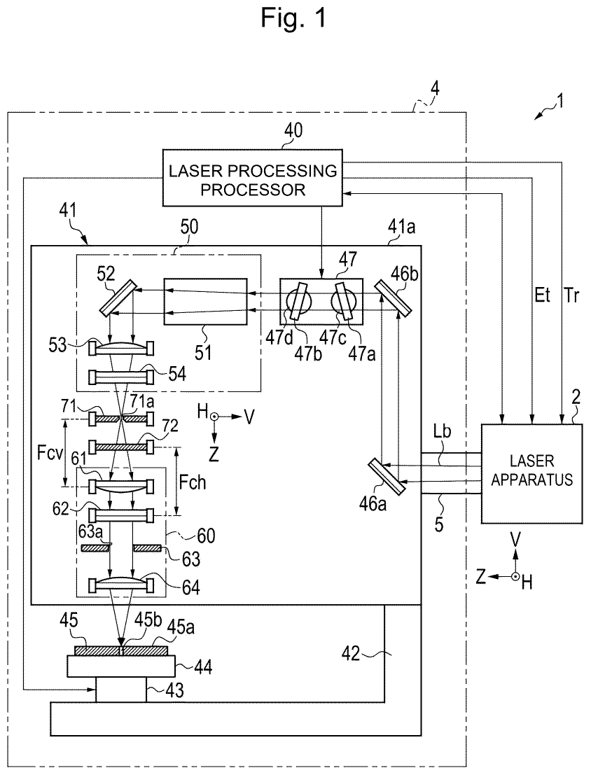

FIG. 1 schematically illustrates a configuration of a laser processing system 1 according to the comparative example. The comparative example is an example recognized by the applicant as known only by the applicant, and is not a publicly known example admitted by the applicant.

The laser processing system 1 mainly includes a laser apparatus 2 and a laser processing apparatus 4. The laser processing system 1 is used for hole processing of forming via holes or the like on a glass substrate for an interposer.

The laser apparatus 2 outputs an ultraviolet pulse laser beam. For example, the laser apparatus 2 is a discharge excitation type laser apparatus that outputs an ultraviolet pulse laser beam using a laser medium such as F₂, ArF, KrF, XeCl, or XeF. In the present disclosure, the laser apparatus 2 is a KrF excimer laser apparatus that outputs an ultraviolet pulse laser beam having a center wavelength of 248.0 nm. Hereinafter, the ultraviolet pulse laser beam output by the laser apparatus 2 is simply referred to as a laser beam Lb.

The laser apparatus 2 and the laser processing apparatus 4 are connected by an optical path pipe 5. The optical path pipe 5 is disposed on an optical path of the laser beam Lb between an exit port of the laser apparatus 2 and an entrance port of the laser processing apparatus 4.

In the present disclosure, a traveling direction of the laser beam Lb output from the laser apparatus 2 is referred to as a Z direction, a direction orthogonal to the Z direction and corresponding to a discharge direction in the laser apparatus 2 is referred to as a V direction, and a direction orthogonal to both the Z direction and the V direction is referred to as an H direction. In an optical device 41, the traveling direction of the laser beam Lb is changed by being reflected by a high reflective mirror to be described later. In the optical device 41, the traveling direction of the laser beam Lb output from an illumination optical system 50 to be described later is defined as the Z direction. In addition, in the optical device 41, the V direction is orthogonal to the Z direction and corresponds to the discharge direction relatively. The V direction corresponds to a “first direction” according to technology of the present disclosure. The H direction corresponds to a “second direction” according to the technology of the present disclosure.

The laser processing apparatus 4 includes a laser processing processor 40, the optical device 41, a frame 42, a moving stage 43, and a table 44. To the frame 42, the optical device 41 and the moving stage 43 are fixed.

The table 44 supports a workpiece 45. The workpiece 45 is an object to be processed, where hole processing is performed. The workpiece 45 is a glass substrate for an interposer, and is, for example, a non-alkali glass substrate. The workpiece 45 may also be a substrate formed of quartz glass, organic materials, silicon monocrystal, ceramics, or the like. In the present comparative example, a hole 45b is formed in the workpiece 45.

The moving stage 43 supports the table 44. The workpiece 45 is fixed on the table 44. The moving stage 43 allows the table 44 to move in the V direction, the H direction, and the Z direction, and changes a position of the workpiece 45 by moving the table 44. The V direction and the H direction are parallel to a surface 45a of the workpiece 45. The Z direction is orthogonal to the surface 45a.

The optical device 41 includes a housing 41a, high reflective mirrors 46a and 46b, an attenuator 47, the illumination optical system 50, a first optical slit 71, a second optical slit 72, and a projection optical system 60. Each component in the optical device 41 is fixed to a non-illustrated holder and is disposed at a predetermined position in the housing 41a.

The high reflective mirror 46a is disposed to reflect the laser beam Lb having passed through the optical path pipe 5, so that the reflected laser beam Lb is incident on the high reflective mirror 46b. The optical path pipe 5 and the housing 41a are purged with a purge gas, for example. The purge gas is a nitrogen gas, an inert gas, or the like, which hardly absorbs the laser beam Lb.

The attenuator 47 is disposed on an optical path of the laser beam Lb reflected by the high reflective mirror 46b in the housing 41a. The attenuator 47 includes, for example, two partial reflective mirrors 47a and 47b and rotating stages 47c and 47d of the partial reflective mirrors. The partial reflective mirrors 47a and 47b are optical elements, a transmittance of which changes depending on an incident angle of the laser beam Lb. For the partial reflective mirrors 47a and 47b, the incident angle of the laser beam Lb is adjusted by the rotating stages 47c and 47d, respectively.

The illumination optical system 50 includes a beam expander 51, a high reflective mirror 52, a first light condensing optical system 53, and a second light condensing optical system 54. The beam expander 51 is disposed on an optical path of the laser beam Lb transmitted through the attenuator 47, to expand a beam diameter of the incident laser beam Lb in the V and H directions by a same magnification and to output it. In the present comparative example, the beam expander 51 has a fixed magnification.

The high reflective mirror 52 is disposed on an optical path of the laser beam Lb output from the beam expander 51. The first light condensing optical system 53 and the second light condensing optical system 54 are disposed sequentially on an optical path of the laser beam Lb reflected by the high reflective mirror 52.

The first light condensing optical system 53 and the second light condensing optical system 54 are cylindrical convex lenses that have optical power in only one direction. The first light condensing optical system 53 has optical power in the V direction and condenses the laser beam Lb in the V direction so as to form a line shape that extends in the H direction at a beam waist position in the V direction of the laser beam Lb. The second light condensing optical system 54 has optical power in the H direction and condenses the laser beam Lb in the H direction so as to form a line shape that extends in the V direction at a beam waist position in the H direction of the laser beam Lb.

Hereinafter, the beam waist position in the V direction is referred to as a “first beam waist position,” and the beam waist position in the H direction is referred to as a “second beam waist position.” In addition, the line shape that extends in the H direction is referred to as a “first line shape,” and the line shape that extends in the V direction is referred to as a “second line shape.”

The first optical slit 71 and the second optical slit 72 are disposed on an optical path of the laser beam Lb output from the illumination optical system 50. The first optical slit 71 has a rectangular opening 71a that extends in the H direction. The second optical slit 72 has a rectangular opening 72a that extends in the V direction.

The first optical slit 71 is disposed at the first beam waist position, and the second optical slit 72 is disposed at the second beam waist position, which is different from where the first optical slit 71 is. The opening 71a of the first optical slit 71 is illuminated by the laser beam Lb in the first line shape. The opening 72a of the second optical slit 72 is illuminated by the laser beam Lb in the second line shape. The openings 71a and 72a are not limited to physical through-holes, but may also be transmission areas that transmit the laser beam Lb.

The projection optical system 60 includes a first collimating optical system 61, a second collimating optical system 62, a diaphragm 63, and an imaging optical system 64. The first collimating optical system 61 and the second collimating optical system 62 are cylindrical convex lenses that have optical power in only one direction. The first collimating optical system 61 has optical power in the V direction and collimates the laser beam Lb transmitted through the first optical slit 71 in the V direction. The second collimating optical system 62 has optical power in the H direction and collimates the laser beam Lb transmitted through the second optical slit 72 in the H direction.

The first collimating optical system 61 is disposed so that the first optical slit 71 is positioned at a front focal position. The second collimating optical system 62 is disposed so that the second optical slit 72 is positioned at the front focal position. It is preferable that a focal length Fcv of the first collimating optical system 61 and a focal length Fch of the second collimating optical system 62 are equal.

The diaphragm 63 is disposed on an optical path of the laser beam Lb collimated by the first collimating optical system 61 and the second collimating optical system 62, and for example, a square opening 63a is formed to have a predetermined numerical aperture.

The imaging optical system 64 is, for example, a convex lens with a spherical surface, and is disposed so as to form an image of the laser beam Lb representing a shape of an overlapping portion of the opening 71a of the first optical slit 71 and the opening 72a of the second optical slit 72 at a rear focal position.

The laser processing processor 40 is capable of transmitting target pulse energy Et and a light emission trigger signal Tr to the laser apparatus 2, and is capable of transmitting and receiving other signals to/from the laser apparatus 2. The target pulse energy Et is a target value of pulse energy of the laser beam Lb. The light emission trigger signal Tr is a trigger signal for making the laser apparatus 2 output one pulse of the laser beam Lb.

In addition, the laser processing processor 40 is a control device that controls the laser apparatus 2 and the moving stage 43 so that each step position is irradiated with the laser beam Lb in a step-and-repeat manner for a processing area where hole processing is required on the surface 45a of the workpiece 45.

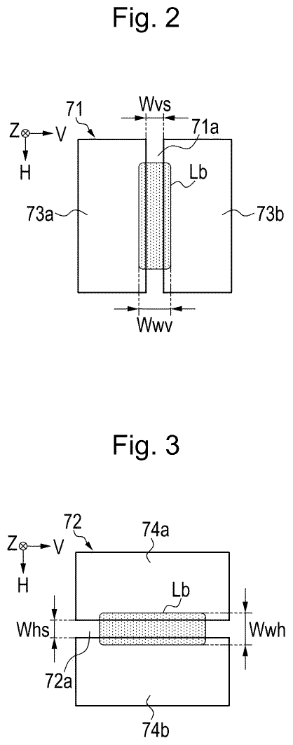

FIG. 2 schematically illustrates a configuration of the first optical slit 71. The first optical slit 71 includes a pair of blades 73a and 73b. The opening 71a is formed by the pair of blades 73a and 73b that are spaced apart in the V direction. A material of the blades 73a and 73b is preferably tungsten (W), molybdenum (Mo), or tantalum (Ta), which is a high melting point metal, and may also be diamond or diamond-like carbon.

When a V-direction width of the laser beam Lb that illuminates the first optical slit 71 is Wwv and a V-direction width of the opening 71a is Wvs, a relationship Wvs <Wwv is satisfied. The laser beam Lb illuminates the first optical slit 71 so as to cover the opening 71a in the V direction. Hereinafter, the width Wwv is referred to as a “first illumination beam width Wwv,” and the width Wvs is referred to as a “first slit width Wvs.”

FIG. 3 schematically illustrates a configuration of the second optical slit 72. The second optical slit 72 includes a pair of blades 74a and 74b. The opening 72a is formed by the pair of blades 74a and 74b that are spaced apart in the H direction. A material of the blades 74a and 74b is preferably tungsten, molybdenum, or tantalum, which is a high melting point metal, and may also be diamond or diamond-like carbon.

When an H-direction width of the laser beam Lb that illuminates the second optical slit 72 is Wwh and an H-direction width of the opening 72a is Whs, a relationship Whs <Wwh is satisfied. The laser beam Lb illuminates the second optical slit 72 so as to cover the opening 72a in the H direction. Hereinafter, the width Wwh is referred to as a “second illumination beam width Wwh,” and the width Whs is referred to as a “second slit width Whs.”

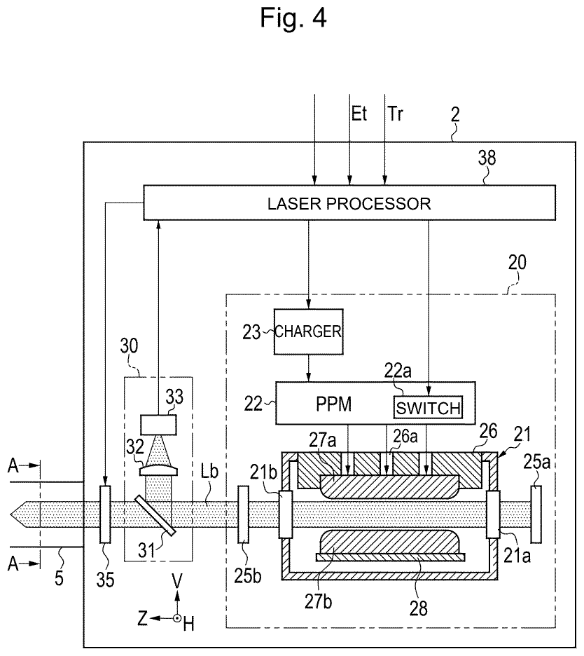

FIG. 4 schematically illustrates a configuration of the laser apparatus 2. The laser apparatus 2 includes an oscillator 20, a monitor module 30, a shutter 35, and a laser processor 38. The oscillator 20 includes an optical resonator formed of a chamber 21, a rear mirror 25a, and an output coupling mirror (OC: Output Coupler) 25b, a charger 23, and a PPM (Pulsed Power Module) 22. The optical resonator of the present comparative example is a Fabry-Perot resonator.

The chamber 21 is provided with windows 21a and 21b. The chamber 21 contains laser gas as the laser medium.

In addition, an opening is formed in the chamber 21, and an electrically insulating plate 26 embedded with a plurality of feedthroughs 26a is provided so as to cover this opening. The PPM 22 is disposed on the electrically insulating plate 26. Inside the chamber 21, a pair of discharge electrodes 27a and 27b as main electrodes and a ground plate 28 are disposed. Discharge surfaces of the pair of discharge electrodes 27a and 27b each have a rectangular shape.

The discharge electrodes 27a and 27b are disposed so that their discharge surfaces face each other to excite the laser medium by discharge. The discharge electrode 27a is supported by the electrically insulating plate 26 on a side opposite to the discharge surface. The discharge electrode 27a is connected to the feedthroughs 26a. The discharge electrode 27b is supported by the ground plate 28 on the side opposite to the discharge surface.

The PPM 22 includes a switch 22a, and a charging capacitor, a pulse transformer, a magnetic compression circuit, and a peaking capacitor that are not illustrated. The peaking capacitor is connected to the feedthroughs 26a via a non-illustrated connecting portion. The charger 23 charges the charging capacitor based on control from the laser processor 38.

The switch 22a is controlled to be turned on/off by the laser processor 38. The laser processor 38 turns on the switch 22a in response to the light emission trigger signal Tr transmitted from the laser processing processor 40.

When the switch 22a is turned on, a current flows from the charging capacitor to a primary side of the pulse transformer, and a reverse current flows to a secondary side of the pulse transformer due to electromagnetic induction. The magnetic compression circuit is connected to the secondary side of the pulse transformer and compresses a pulse width of a current pulse. The peaking capacitor is charged by this current pulse. When a voltage of the peaking capacitor reaches a breakdown voltage of the laser gas, insulation breakdown occurs in the laser gas between the discharge electrodes 27a and 27b, resulting in discharge. This discharge generates one pulse of the laser beam Lb.

The rear mirror 25a is formed by coating a high reflective film on a flat substrate. The output coupling mirror 25b is formed by coating a partial reflective film on a flat substrate. The chamber 21 is disposed between the rear mirror 25a and the output coupling mirror 25b. The laser beam Lb generated in the chamber 21 is amplified by the optical resonator and is output from the output coupling mirror 25b.

The monitor module 30 includes a beam splitter 31, a light condensing lens 32, and a photosensor 33. The beam splitter 31 is disposed on an optical path of the laser beam Lb output from the output coupling mirror 25b and reflects a portion of the laser beam Lb. The light condensing lens 32 is disposed on an optical path of the laser beam Lb reflected by the beam splitter 31, and condenses the laser beam Lb onto the photosensor 33. The photosensor 33 measures the pulse energy of the laser beam Lb and transmits a measurement value to the laser processor 38.

The laser processor 38 controls the pulse energy of the laser beam Lb output from the laser apparatus 2 to be the target pulse energy Et by changing a charging voltage of the charger 23 based on the measurement value of the pulse energy by the photosensor 33.

The shutter 35 is disposed on an optical path of the laser beam Lb transmitted through the beam splitter 31. The shutter 35 is opened and closed in response to commands from the laser processor 38. The laser processor 38 controls output of the laser beam Lb from the laser apparatus 2 by controlling the shutter 35.

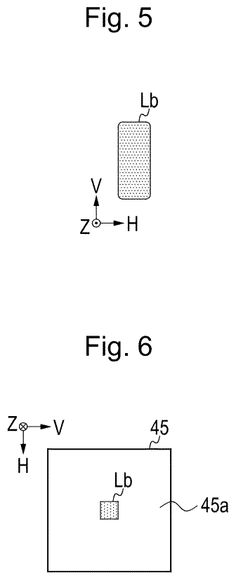

FIG. 5 schematically illustrates a beam shape of the laser beam Lb cut on a VH plane along a line A-A illustrated in FIG. 4. The beam shape is a rectangular shape that is longer in the V direction than in the H direction.

### 1.2 Operation

Next, the operation of the laser processing system 1 according to the comparative example will be described. First, the laser processing processor 40 controls the moving stage 43 so that the rear focal position of the imaging optical system 64 coincides with the surface 45a of the workpiece 45.

Next, the laser processing processor 40 transmits the target pulse energy Et to the laser apparatus 2 and controls a transmittance Ta of the attenuator 47 so that a fluence of the laser beam Lb with which the surface 45a of the workpiece 45 is irradiated becomes a target fluence Ft. Here, the fluence refers to energy density of the laser beam Lb with which a certain position is irradiated. The target fluence Ft is an optimum fluence for processing that exceeds an ablation threshold on the surface 45a of the workpiece 45.

Upon receiving the target pulse energy Et, the laser processor 38 closes the shutter 35 and sets the charging voltage corresponding to the target pulse energy Et to the charger 23. The laser processor 38 inputs a trigger to the switch 22a of the PPM 22 in response to a non-illustrated internal trigger. As a result, the oscillator 20 performs spontaneous oscillation.

The laser beam Lb output from the oscillator 20 is sampled by the monitor module 30, and the pulse energy is measured. The laser processor 38 controls the charging voltage of the charger 23 so that a difference ΔE between the measurement value of the pulse energy and the target pulse energy Et approaches zero.

When the difference ΔE falls within an allowable range, the laser processor 38 transmits a permission signal to the laser processing processor 40 to open the shutter 35. Upon receiving the permission signal, the laser processing processor 40 transmits the light emission trigger signal Tr of a predetermined pulse number N at a predetermined repetition frequency f to the laser apparatus 2. As a result, in synchronization with the light emission trigger signal Tr, the laser beam Lb transmitted through the beam splitter 31 of the monitor module 30 enters the optical device 41 of the laser processing apparatus 4.

The laser beam Lb incident on the optical device 41 is transmitted through the attenuator 47 via the high reflective mirrors 46a and 46b and enters the illumination optical system 50. The laser beam Lb incident on the illumination optical system 50 is expanded in beam diameter by the beam expander 51. The laser beam Lb with an expanded beam diameter is reflected by the high reflective mirror 52, enters the first light condensing optical system 53, is transmitted through the first light condensing optical system 53, and enters the second light condensing optical system 54. The laser beam Lb is condensed into the first line shape by the first light condensing optical system 53 and illuminates the first optical slit 71. In addition, the laser beam Lb is condensed into the second line shape by the second light condensing optical system 54 and illuminates the second optical slit 72.

The laser beam Lb transmitted through the first optical slit 71 and the second optical slit 72 enters the projection optical system 60. The laser beam Lb incident on the projection optical system 60 is collimated in the V direction by the first collimating optical system 61, is collimated in the H direction by the second collimating optical system 62, and enters the diaphragm 63. The laser beam Lb that has passed through the opening 63a of the diaphragm 63 is imaged on the surface 45a of the workpiece 45 by the imaging optical system 64.

As illustrated in FIG. 6, a rectangular image of the laser beam Lb representing the shape of the overlapping portion of the opening 71a of the first optical slit 71 and the opening 72a of the second optical slit 72 is formed on the surface 45a of the workpiece 45. By repeatedly irradiating the workpiece 45 with the laser beam Lb, ablation occurs on the workpiece 45, and hole processing is performed.

### 1.3 Problem

In the laser processing apparatus 4 according to the comparative example, the laser beam Lb is condensed at different positions in the V and H directions, and the formed line-shape laser beam Lb is used to illuminate the first optical slit 71 and the second optical slit 72.

However, in the laser processing apparatus 4 according to the comparative example, the position of the laser beam Lb at illumination positions of the first optical slit 71 and the second optical slit 72 fluctuates due to influences of output fluctuation including angle fluctuation of the laser beam Lb output by the laser apparatus 2, vibrations of the optical system, and environmental factors such as changes in temperature and humidity. As a result, the transmittance of the laser beam Lb transmitted through the first optical slit 71 and the second optical slit 72 decreases. In particular, position fluctuation of the laser beam Lb in the V direction corresponding to the discharge direction is large, and transmittance fluctuation is significantly observed. For example, even if a design value of the transmittance is 80%, the transmittance may decrease to about 20% due to the influences.

The present disclosure provides a laser processing apparatus capable of suppressing position fluctuation of a laser beam at illumination positions of optical slits and improving a transmittance.

### 2. First Embodiment

The laser processing system 1 according to the first embodiment of the present disclosure will be described. Any components same as those described above are denoted by same signs, and any redundant description thereof is omitted unless specific description is needed.

### 2.1 Configuration

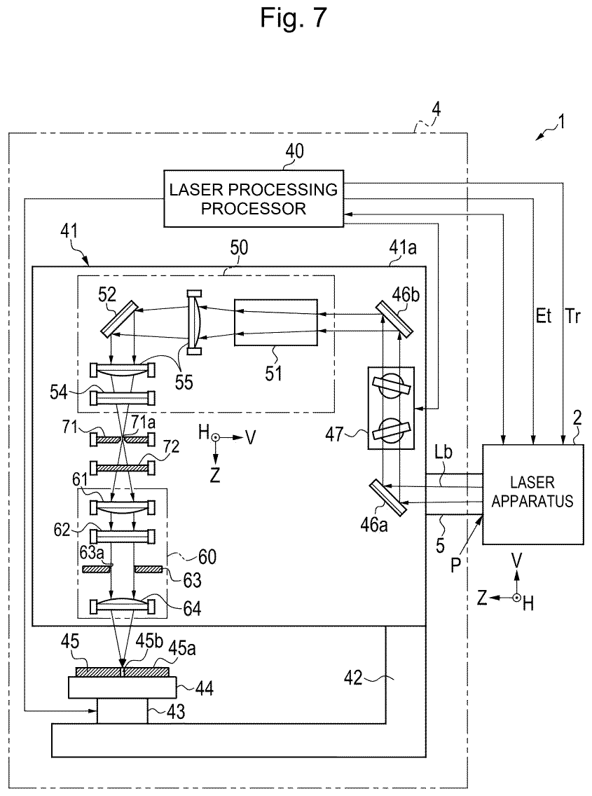

FIG. 7 schematically illustrates a configuration of the laser processing system 1 according to the first embodiment. The laser processing system 1 differs from the configuration of the laser processing system 1 according to the comparative example only in the configuration of the optical device 41.

In the present embodiment, the illumination optical system 50 includes a first relay optical system 55 instead of the first light condensing optical system 53. The first relay optical system 55 is disposed on an upstream side of the first optical slit 71. Specifically, the first relay optical system 55 is disposed on the optical path of the laser beam Lb output from the beam expander 51 on the upstream side of the first optical slit 71.

The first relay optical system 55 is configured to transfer and reduce a beam image at an output position P of the laser beam Lb of the laser apparatus 2 in the V direction and to illuminate the first optical slit 71. Here, the output position P refers to a position of the output coupling mirror 25b included in the laser apparatus 2.

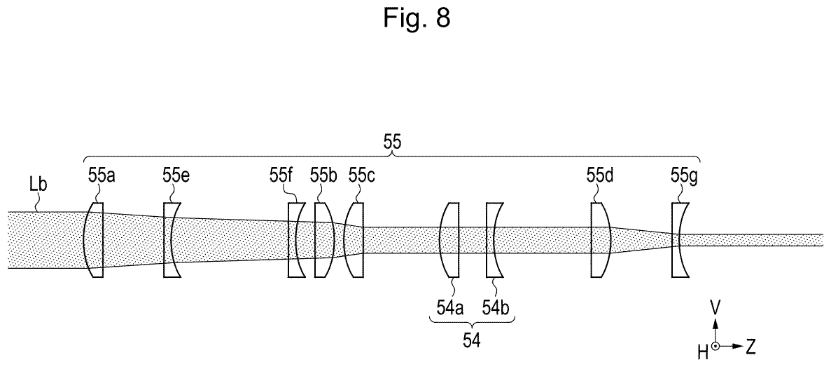

FIG. 8 illustrates a specific configuration example of the first relay optical system 55 and the second light condensing optical system 54. The first relay optical system 55 is formed of seven lenses. Specifically, the first relay optical system 55 is configured by combining four cylindrical convex lenses 55a to 55d having optical power in the V direction and three cylindrical concave lenses 55e to 55g having optical power in the V direction.

The second light condensing optical system 54 is configured by combining one cylindrical convex lens 54a and one cylindrical concave lens 54b. The second light condensing optical system 54 is disposed, for example, between the cylindrical convex lens 55c and the cylindrical convex lens 55d. In addition, the high reflective mirror 52 is disposed, for example, between the cylindrical concave lens 55e and the cylindrical concave lens 55f.

Further, while the attenuator 47 is disposed between the high reflective mirror 46a and the high reflective mirror 46b in the present embodiment, the position of the attenuator 47 is not limited and it may be disposed between the high reflective mirror 46b and the beam expander 51 similarly to the comparative example.

A reduction magnification in the V direction of the beam image by the first relay optical system 55 is within a range of 1/15 to ¼. A curvature radius relating to the V direction of the cylindrical convex lenses 55a to 55d is within a range of 50 mm to 500 mm. The curvature radius relating to the V direction of the cylindrical concave lenses 55e to 55g is within the range of 50 mm to 150 mm.

A composite focal length of the first relay optical system 55 is within a range of 2 m to 30 m, and is preferably 25 m. Here, the composite focal length refers to an effective focal length of the entire optical system formed by combining the lenses. The composite focal length of the first relay optical system 55 corresponds to an optical path length from the output position P to the first optical slit 71. That is, the first relay optical system 55 is disposed so that its transfer image plane coincides with a surface of the first optical slit 71.

In addition, the first illumination beam width Wwv is within a range of 1.5 to 3 times the first slit width Wvs. The width Wwv is defined by a 1/e² diameter. The 1/e² diameter refers to a diameter at a point where the intensity of the beam is attenuated to 1/e² of a maximum value, based on the central intensity, in a spatial intensity distribution of the beam.

The configuration of the first relay optical system 55 is not limited to the above configuration, and is appropriately changed according to a size of the opening 71a of the first optical slit 71 and an optical path length between the laser apparatus 2 and the first optical slit 71.

### 2.2 Operation

Next, the operation of the laser processing system 1 according to the first embodiment will be described. The operation of the laser processing system 1 according to the present embodiment differs from the comparative example only in actions within the optical device 41. Hereinafter, only points different from the comparative example will be described.

The laser beam Lb incident on the illumination optical system 50 is expanded in beam diameter by the beam expander 51. Subsequently, the laser beam Lb passes through the first relay optical system 55. As a result, the first optical slit 71 is illuminated by the laser beam Lb for which the beam image at the output position P is transferred in the V direction and is also reduced in the V direction. Thus, the shape of the laser beam Lb that illuminates the first optical slit 71 is the first line shape.

In the present embodiment, similarly to the comparative example, a rectangular image of the laser beam Lb representing the shape of the overlapping portion of the opening 71a of the first optical slit 71 and the opening 72a of the second optical slit 72 is formed on the surface 45a of the workpiece 45. By repeatedly irradiating the workpiece 45 with the laser beam Lb, ablation occurs on the workpiece 45, and hole processing is performed.

### 2.3 Effect

In the present embodiment, considering that the position fluctuation of the laser beam Lb output from the laser apparatus 2 is particularly large in the V direction, the first relay optical system 55 is applied to illumination of the first optical slit 71 corresponding to the V direction. Thus, the first optical slit 71 is illuminated by the laser beam Lb for which the beam image at the output position P of the laser apparatus 2 is transferred in the V direction and is also reduced in the V direction.

In a case of using the first light condensing optical system 53 of the comparative example, the position fluctuation of the laser beam Lb at the illumination position of the first optical slit 71 is large, leading to a decrease in the transmittance. However, in the present embodiment, by using the first relay optical system 55, the beam image at the output position P of the laser apparatus 2 is transferred in the V direction and is also reduced in the V direction, thereby suppressing the position fluctuation in the V direction of the laser beam Lb at the illumination position of the first optical slit 71.

For example, in the case of using the first light condensing optical system 53, even if the design value of the transmittance is about 80%, the actual transmittance may decrease to about 20% due to the position fluctuation of the laser beam Lb. On the other hand, in the case of using the first relay optical system 55, under same conditions, although the design value of the transmittance is as small as about 47%, the actual transmittance is maintained at about 44%, and the transmittance is improved by more than twice compared to the comparative example.

Further, in the present embodiment, since an irradiation state of the laser beam Lb transmitted through the first optical slit 71 is stabilized, the fluence and an imaging state on the surface 45a of the workpiece 45 are also stabilized, enabling high quality hole processing.

### 3. Modifications of First Embodiment

Next, various modifications of the first embodiment will be described.

### 3.1 First Modification

The first modification differs from the first embodiment only in that an optical axis stabilization system for stabilizing an optical axis of the laser beam Lb to the illumination optical system 50 is added in the optical device 41.

### 3.1.1 Configuration

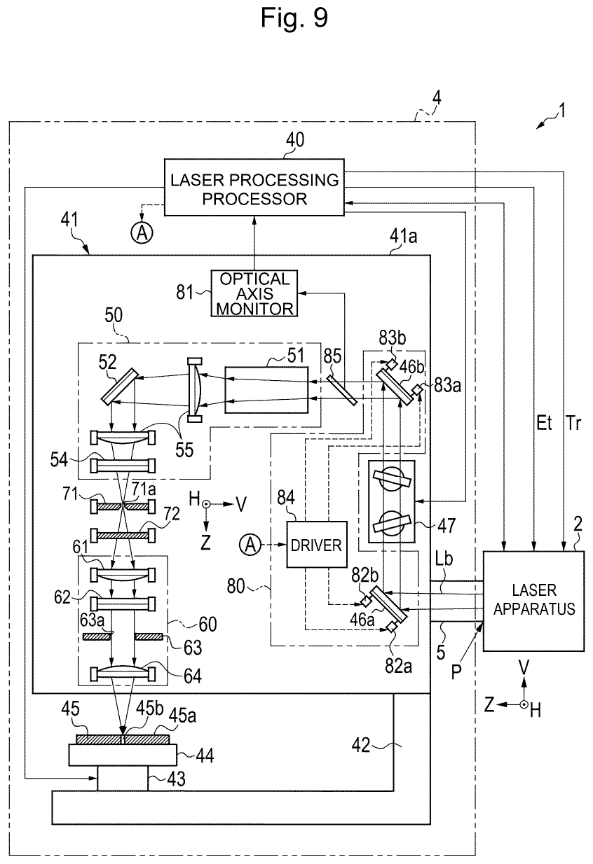

FIG. 9 schematically illustrates a configuration of the laser processing system 1 according to the first modification. The optical axis stabilization system includes a beam steering device 80 that adjusts the optical axis and an optical axis monitor 81 that monitors the optical axis.

The beam steering device 80 includes actuators 82a and 82b attached to the high reflective mirror 46a, actuators 83a and 83b attached to the high reflective mirror 46b, and a driver 84. The actuators 82a and 82b change a posture of the high reflective mirror 46a around two axes that are orthogonal to each other. The actuators 83a and 83b change a posture of the high reflective mirror 46b around two axes that are orthogonal to each other. The driver 84 drives the actuators 82a and 82b and the actuators 83a and 83b based on instructions from the laser processing processor 40.

A beam splitter 85 is disposed on an optical path of the laser beam Lb between the beam steering device 80 and the illumination optical system 50. The beam splitter 85 reflects a portion of the laser beam Lb output from the beam steering device 80 and causes it to enter the optical axis monitor 81. The optical axis monitor 81 measures a position of the optical axis based on the laser beam Lb incident from the beam splitter 85.

### 3.1.2 Operation

The operation of the laser processing system 1 according to the present modification is same as that of the first embodiment, except that an optical axis stabilizing operation is performed during a hole processing operation.

The laser processing processor 40 measures and stores a target position of the optical axis at which the laser beam Lb is transmitted through the first optical slit 71 and the second optical slit 72 with a high transmittance, in advance. During the hole processing operation, the laser processing processor 40 acquires the measured value of the optical axis position from the optical axis monitor 81 and controls the driver 84 to change the postures of the high reflective mirrors 46a and 46b so that the measured value approaches the target position.

### 3.1.3 Effect

In the present modification, by performing the optical axis stabilizing operation during the hole processing operation, the transmittance of the laser beam Lb transmitted through the first optical slit 71 and the second optical slit 72 can be maintained at a high value. As a result, the fluence and the imaging state on the surface 45a of the workpiece 45 are further stabilized, enabling higher quality hole processing.

### 3.2 Second Modification

The second modification differs from the first modification only in the configuration of the projection optical system 60.

### 3.2.1 Configuration

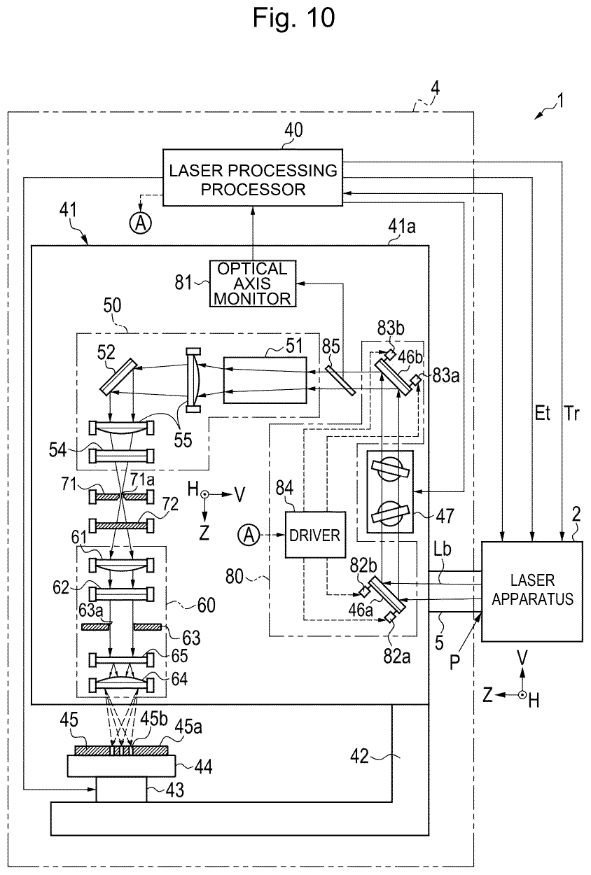

FIG. 10 schematically illustrates a configuration of the laser processing system 1 according to the second modification. In the present modification, a diffractive optical element (DOE) 65 is disposed on an optical path of the laser beam Lb between the diaphragm 63 and the imaging optical system 64 in the projection optical system 60.

The DOE 65 is an optical element that utilizes a light diffraction phenomenon, and is produced by processing a fine structure designed by simulation for example on a substrate using microfabrication technology. In general, the DOE can convert a laser beam into various patterns. In the present disclosure, the DOE 65 converts the laser beam Lb into a multi-point pattern.

### 3.2.2 Operation

The operation of the laser processing system 1 according to the present modification differs from the first modification only in the action of the projection optical system 60. In the present modification, the laser beam Lb having passed through the opening 63a of the diaphragm 63 is incident on the DOE 65. The DOE 65 divides the incident laser beam Lb into a plurality of beams at different angles and causes them to enter the imaging optical system 64.

The imaging optical system 64 forms a plurality of images of the beams representing the shape of the overlapping portion of the opening 71a of the first optical slit 71 and the opening 72a of the second optical slit 72, that is, the multi-point patterns, on the surface 45a of the workpiece 45. By repeatedly irradiating the workpiece 45 with the laser beam Lb divided into the beams, ablation occurs on the workpiece 45, and a plurality of holes 45b are simultaneously processed.

### 3.2.3 Effect

In the present modification, by using the DOE 65, the holes 45b can be simultaneously processed on the workpiece 45.

While the DOE 65 is the optical element separate from the imaging optical system 64 in the present modification, the DOE 65 may also be an optical element that includes functions of the imaging optical system 64. That is, the DOE 65 may divide the laser beam Lb having passed through the diaphragm 63 into the beams and form images of the beams on the surface 45a of the workpiece 45. In this case, it is not necessary to dispose the imaging optical system 64.

In addition, the present modification may be applied to the laser processing system 1 according to the first embodiment.

### 4. Second Embodiment

The laser processing system 1 according to the second embodiment of the present disclosure will be described. Any components same as those described above are denoted by same signs, and any redundant description thereof is omitted unless specific description is needed.

### 4.1 Configuration

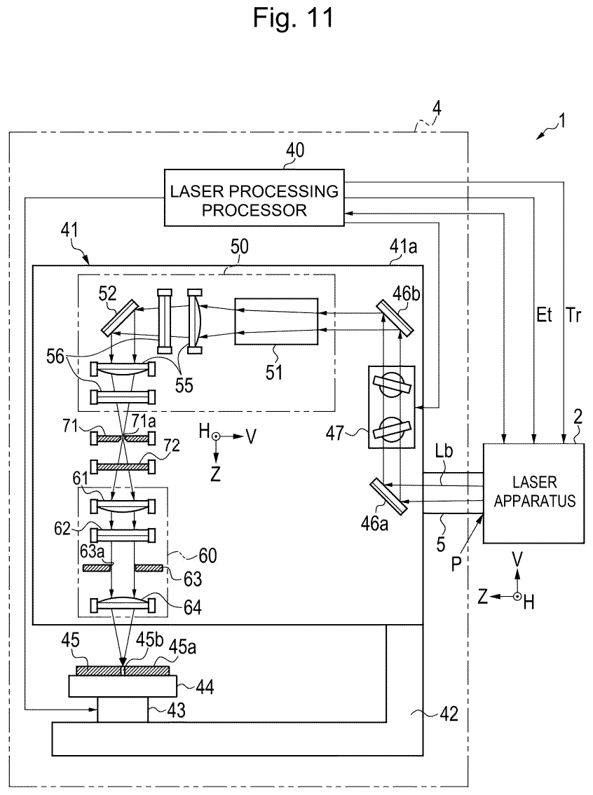

FIG. 11 schematically illustrates a configuration of the laser processing system 1 according to the second embodiment. The laser processing system 1 differs from the configuration of the laser processing system 1 according to the first embodiment only in the configuration of the optical device 41.

In the present embodiment, the illumination optical system 50 includes a second relay optical system 56 instead of the second light condensing optical system 54. That is, in the present embodiment, in addition to the first relay optical system 55, the second relay optical system 56 is applied to the illumination of the second optical slit 72.

The second relay optical system 56 is disposed on an upstream side of the second optical slit 72. Specifically, the second relay optical system 56 is disposed on the optical path of the laser beam Lb output from the beam expander 51 on the upstream side of the second optical slit 72.

The second relay optical system 56 is configured to transfer and reduce the beam image at the output position P of the laser beam Lb of the laser apparatus 2 in the H direction and to illuminate the second optical slit 72.

The second relay optical system 56 is configured similarly to the first relay optical system 55. Although not illustrated in the figure, the second relay optical system 56 is configured by combining four cylindrical convex lenses having optical power in the H direction and three cylindrical concave lenses having optical power in the H direction.

A reduction magnification in the H direction of the beam image by the second relay optical system 56 is within the range of 1/15 to ¼. The curvature radius relating to the H direction of the cylindrical convex lenses included in the second relay optical system 56 is within the range of 50 mm to 500 mm. The curvature radius relating to the H direction of the cylindrical concave lenses included in the second relay optical system 56 is within the range of 50 mm to 150 mm.

A composite focal length of the second relay optical system 56 is within the range of 2 m to 30 m, and is preferably 25 m. The composite focal length of the second relay optical system 56 corresponds to an optical path length from the output position P to the second optical slit 72. That is, the second relay optical system 56 is disposed so that its transfer image plane coincides with a surface of the second optical slit 72.

In addition, the second illumination beam width Wwh is within a range of 1.5 to 3 times the second slit width Whs. The width Wwh is defined by the 1/e² diameter.

The configuration of the second relay optical system 56 is not limited to the above configuration, and is appropriately changed according to a size of the opening 72a of the second optical slit 72 and an optical path length between the laser apparatus 2 and the second slit optical slit 72.

### 4.2 Operation

Next, the operation of the laser processing system 1 according to the second embodiment will be described. The operation of the laser processing system 1 according to the present embodiment differs from the first embodiment only in the actions within the optical device 41. Hereinafter, only points different from the first embodiment will be described.

The laser beam Lb incident on the illumination optical system 50 is expanded in beam diameter by the beam expander 51. Subsequently, the laser beam Lb passes through the first relay optical system 55 and the second relay optical system 56. As a result, the first optical slit 71 is illuminated by the laser beam Lb for which the beam image at the output position P is transferred in the V direction and is also reduced in the V direction, and the second optical slit 72 is illuminated by the laser beam Lb for which the beam image at the output position P is transferred in the H direction and is also reduced in the H direction. Thus, the shape of the laser beam Lb that illuminates the first optical slit 71 is the first line shape, and the shape of the laser beam Lb that illuminates the second optical slit 72 is the second line shape.

In the present embodiment, similarly to the comparative example, a rectangular image of the laser beam Lb representing the shape of the overlapping portion of the opening 71a of the first optical slit 71 and the opening 72a of the second optical slit 72 is formed on the surface 45a of the workpiece 45. By repeatedly irradiating the workpiece 45 with the laser beam Lb, ablation occurs on the workpiece 45, and hole processing is performed.

### 4.3 Effect

In the present embodiment, the first relay optical system 55 and the second relay optical system 56 are applied to the illumination of the first optical slit 71 and the second optical slit 72. Thus, the position fluctuation of the laser beam Lb output from the laser apparatus 2 can be suppressed in both the V direction and the H directions. As a result, the fluence and the imaging state on the surface 45a of the workpiece 45 are further stabilized, enabling higher quality hole processing.

### 5. Modifications of Second Embodiment

Next, various modifications of the second embodiment will be described.

### 5.1 First Modification

The first modification differs from the second embodiment only in that the optical axis stabilization system for stabilizing an optical axis of the laser beam Lb to the illumination optical system 50 is added in the optical device 41.

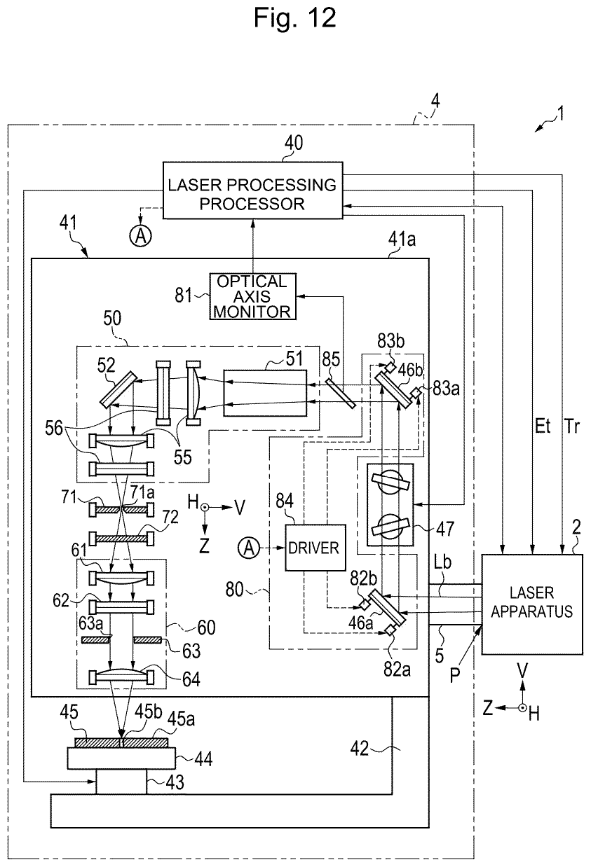

FIG. 12 schematically illustrates a configuration of the laser processing system 1 according to the first modification. The optical axis stabilization system includes the beam steering device 80 that adjusts the optical axis and the optical axis monitor 81 that monitors the optical axis. Since the configuration and the operation of the beam steering device 80 and the optical axis monitor 81 are same as those in the first modification of the first embodiment, the description thereof is omitted.

According to the present modification, the transmittance of the laser beam Lb transmitted through the first optical slit 71 and the second optical slit 72 can be maintained at a high value, enabling higher quality hole processing.

### 5.2 Second Modification

The second modification differs from the first modification only in the configuration of the projection optical system 60.

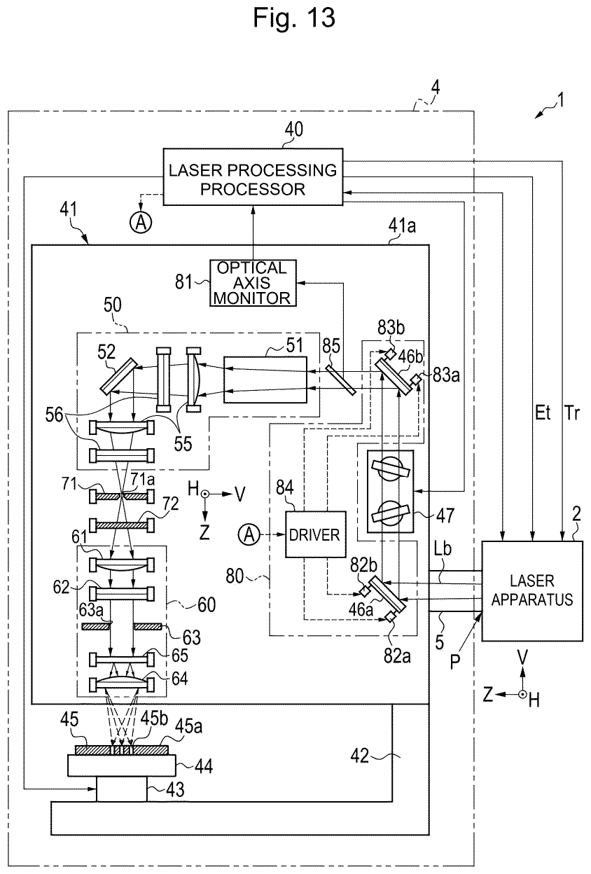

FIG. 13 schematically illustrates a configuration of the laser processing system 1 according to the second modification. In the present modification, the DOE 65 is disposed on the optical path of the laser beam Lb between the diaphragm 63 and the imaging optical system 64 in the projection optical system 60. Since the configuration and the operation of the DOE 65 are same as those in the second modification of the first embodiment, the description thereof is omitted.

According to the present modification, the holes 45b can be simultaneously processed on the workpiece 45. It is also possible to apply the present modification to the laser processing system 1 according to the second embodiment.

### 6. Optical Axis Monitor

Next, a specific configuration of the optical axis monitor 81 will be described.

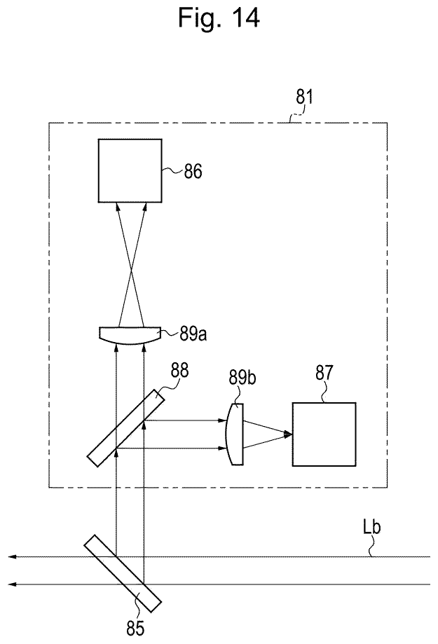

FIG. 14 schematically illustrates the configuration of the optical axis monitor 81. The optical axis monitor 81 includes a first beam profiler 86, a second beam profiler 87, a beam splitter 88, a transfer lens 89a, and a light condensing lens 89b. The beam splitter 88 is disposed on an optical path of the laser beam Lb reflected by the beam splitter 85 illustrated in the first modification of the first and second embodiments.

The transfer lens 89a is disposed on an optical path of the laser beam Lb transmitted through the beam splitter 88, and transfers the incident laser beam Lb to the first beam profiler 86. The first beam profiler 86 measures a position of a sectional intensity profile of the laser beam Lb.

The light condensing lens 89b is disposed on an optical path of the laser beam Lb reflected by the beam splitter 88, and condenses the incident laser beam Lb onto the second beam profiler 87. The second beam profiler 87 measures a center position of a focal point.

The optical axis of the laser beam Lb can be measured from the position of the sectional intensity profile measured by the first beam profiler 86 and the center position of the focal point measured by the second beam profiler 87.

### 7. Electronic Device Manufacturing Method

A laser processing method according to the embodiments and the modifications can be applied to formation of through-holes in a glass substrate provided in an interposer 102 in manufacturing an electronic device 100 below.

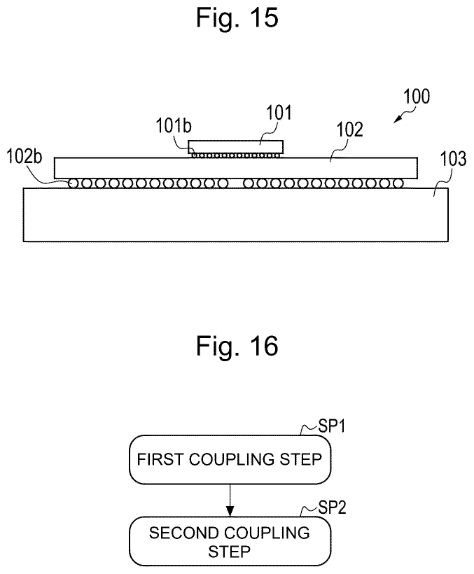

FIG. 15 schematically illustrates a configuration of the electronic device 100. The electronic device 100 illustrated in FIG. 15 includes an integrated circuit chip 101, the interposer 102, and a circuit board 103. The integrated circuit chip 101 is, for example, a chip-like integrated circuit board in which an integrated circuit is formed on a silicon substrate. The integrated circuit chip 101 is provided with a plurality of bumps 101b electrically connected to the integrated circuit.

The interposer 102 includes an insulating glass substrate in which a plurality of through-holes are formed, and a conductor that electrically connects front and back surfaces of the glass substrate is provided in each of the through-holes. A plurality of lands to be connected to the bumps 101b provided in the integrated circuit chip 101 are formed on one surface of the interposer 102, and each land is electrically connected to one of the conductors in the through-holes. A plurality of bumps 102b are provided on the other surface of the interposer 102, and each bump 102b is electrically connected to one of the conductors in the through-holes.

A plurality of lands to be connected to the bumps 102b respectively are formed on one surface of the circuit board 103. In addition, the circuit board 103 includes a plurality of terminals electrically connected to the lands.

FIG. 16 illustrates a method of manufacturing the electronic device 100. As illustrated in FIG. 16, the method of manufacturing the electronic device 100 in the present description includes a first coupling step SP1 and a second coupling step SP2. In the first coupling step SP1, the integrated circuit chip 101 and the interposer 102 are coupled. Specifically, each bump 101b of the integrated circuit chip 101 is disposed on each land of the interposer 102 and the bump 101b and the land are electrically connected to each other. Thus, the integrated circuit chip 101 and the interposer 102 are electrically connected to each other.

In the second coupling step SP2, the interposer 102 and the circuit board 103 are coupled. Specifically, each bump 102b of the interposer 102 is disposed on each land of the circuit board 103, and the bump 102b and the land are electrically connected to each other. Thus, the integrated circuit chip 101 is electrically connected to the circuit board 103 via the interposer 102. Through the steps, the electronic device 100 is manufactured.

### 7. Configuration Example of Laser Processing Processor

In the present disclosure, the laser processing processor 40 is configured, for example, by a CPU (Central Processing Unit). The laser processing processor 40 executes various kinds of the processing based on a program stored in a memory. Some or all of functions of the laser processing processor 40 may be implemented by using an integrated circuit such as an FPGA (Field Programmable Gate Array) or an ASIC (Application Specific Integrated Circuit). The laser processing processor 40 stores various kinds of the data in the memory.

The description above is intended to be illustrative and the present disclosure is not limited thereto. Therefore, it would be obvious to those skilled in the art that various modifications to the embodiments of the present disclosure would be possible without departing from the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser processing apparatus that performs hole processing by irradiating a workpiece with a laser beam output from an output coupling mirror of a laser apparatus, the laser processing apparatus comprising:
a first optical slit disposed on an optical path of the laser beam and having an opening that extends in a second direction orthogonal to a first direction;
a second optical slit disposed at a position different from the first optical slit on the optical path of the laser beam and having an opening that extends in the first direction;
an illumination optical system including a first relay optical system configured to transfer and reduce a beam image of the laser beam at a position of the output coupling mirror in the first direction and to illuminate the first optical slit, and a light condensing optical system configured to condense the laser beam in the second direction and to illuminate the second optical slit; and
a projection optical system configured to form an image of the laser beam transmitted through the first optical slit and the second optical slit on a surface of the workpiece to represent a shape of an overlapping portion of the opening of the first optical slit and the opening of the second optical slit.

2. The laser processing apparatus according to claim 1, wherein
the first relay optical system includes a cylindrical convex lens having optical power in the first direction and a cylindrical concave lens having optical power in the first direction.

3. The laser processing apparatus according to claim 1, wherein
a composite focal length of the first relay optical system is within a range of 2 m to 30 m.

4. The laser processing apparatus according to claim 1, wherein
a reduction magnification in the first direction of the beam image by the first relay optical system is within a range of 1/15 to ¼.

5. The laser processing apparatus according to claim 1, wherein
a width in the first direction of the laser beam that illuminates the first optical slit is within a range of 1.5 to 3 times a width in the first direction of the first optical slit.

6. The laser processing apparatus according to claim 1, comprising
a beam steering device that can adjust a position of an optical axis of the laser beam incident on the illumination optical system.

7. The laser processing apparatus according to claim 1, wherein
the projection optical system includes:
a first collimating optical system configured to collimate the laser beam transmitted through the first optical slit in the first direction;
a second collimating optical system configured to collimate the laser beam transmitted through the second optical slit in the second direction;
an imaging optical system configured to form an image of the laser beam transmitted through the first optical slit and the second optical slit on the surface of the workpiece; and
a diaphragm disposed between the first optical slit and the second optical slit and the imaging optical system.

8. The laser processing apparatus according to claim 1, wherein
the projection optical system includes:
a first collimating optical system configured to collimate the laser beam transmitted through the first optical slit in the first direction;
a second collimating optical system configured to collimate the laser beam transmitted through the second optical slit in the second direction;
a diaphragm disposed on the optical path of the laser beam transmitted through the first optical slit and the second optical slit; and
a diffractive optical element configured to divide the laser beam having passed through the diaphragm into a plurality of beams and to form images of the beams on the surface of the workpiece.

9. The laser processing apparatus according to claim 8, comprising
a beam steering device that can adjust a position of an optical axis of the laser beam incident on the illumination optical system.

10. A laser processing apparatus that performs hole processing by irradiating a workpiece with a laser beam output from an output coupling mirror of a laser apparatus, the laser processing apparatus comprising:
a first optical slit disposed on an optical path of the laser beam and having an opening that extends in a second direction orthogonal to a first direction;
a second optical slit disposed at a position different from the first optical slit on the optical path of the laser beam and having an opening that extends in the first direction;
an illumination optical system including a first relay optical system configured to transfer and reduce a beam image of the laser beam at a position of the output coupling mirror in the first direction and to illuminate the first optical slit, and a second relay optical system configured to transfer and reduce the beam image at the position of the output coupling mirror in the second direction and to illuminate the second optical slit; and
a projection optical system configured to form an image of the laser beam transmitted through the first optical slit and the second optical slit on a surface of the workpiece to represent a shape of an overlapping portion of the opening of the first optical slit and the opening of the second optical slit.

11. The laser processing apparatus according to claim 10, wherein
the first relay optical system includes a cylindrical convex lens having optical power in the first direction and a cylindrical concave lens having optical power in the first direction, and
the second relay optical system includes a cylindrical convex lens having optical power in the second direction and a cylindrical concave lens having optical power in the second direction.

12. The laser processing apparatus according to claim 10, wherein
a composite focal length of the first relay optical system is within a range of 2 m to 30 m, and
a composite focal length of the second relay optical system is within a range of 2 m to 30 m.

13. The laser processing apparatus according to claim 10, wherein
a reduction magnification in the first direction of the beam image by the first relay optical system is within a range of 1/15 to ¼, and
a reduction magnification in the second direction of the beam image by the second relay optical system is within a range of 1/15 to ¼.

14. The laser processing apparatus according to claim 10, wherein
a width in the first direction of the laser beam that illuminates the first optical slit is within a range of 1.5 to 3 times a width in the first direction of the first optical slit, and
a width in the second direction of the laser beam that illuminates the second optical slit is within a range of 1.5 to 3 times a width in the second direction of the second optical slit.

15. The laser processing apparatus according to claim 10, comprising
a beam steering device that can adjust a position of an optical axis of the laser beam incident on the illumination optical system.

16. The laser processing apparatus according to claim 10, wherein
the projection optical system includes:
a first collimating optical system configured to collimate the laser beam transmitted through the first optical slit in the first direction;
a second collimating optical system configured to collimate the laser beam transmitted through the second optical slit in the second direction;
an imaging optical system configured to form an image of the laser beam transmitted through the first optical slit and the second optical slit on the surface of the workpiece; and
a diaphragm disposed between the first optical slit and the second optical slit and the imaging optical system.

17. The laser processing apparatus according to claim 10, wherein
the projection optical system includes:
a first collimating optical system configured to collimate the laser beam transmitted through the first optical slit in the first direction;
a second collimating optical system configured to collimate the laser beam transmitted through the second optical slit in the second direction;
a diaphragm disposed on the optical path of the laser beam transmitted through the first optical slit and the second optical slit; and
a diffractive optical element configured to divide the laser beam having passed through the diaphragm into a plurality of beams and to form images of the beams on the surface of the workpiece.

18. The laser processing apparatus according to claim 17, comprising
a beam steering device that can adjust a position of an optical axis of the laser beam incident on the illumination optical system.

19. An electronic device manufacturing method comprising:
forming a plurality of through-holes on a glass substrate as a workpiece by a laser processing apparatus that performs hole processing by irradiating the workpiece with a laser beam output from an output coupling mirror of a laser apparatus, the laser processing apparatus including
a first optical slit disposed on an optical path of the laser beam and having an opening that extends in a second direction orthogonal to a first direction,
a second optical slit disposed at a position different from the first optical slit on the optical path of the laser beam and having an opening that extends in the first direction,
an illumination optical system including a first relay optical system configured to transfer and reduce a beam image of the laser beam at a position of the output coupling mirror in the first direction and to illuminate the first optical slit, and a second relay optical system configured to transfer and reduce the beam image at the position of the output coupling mirror in the second direction and to illuminate the second optical slit, and
a projection optical system configured to form an image of the laser beam transmitted through the first optical slit and the second optical slit on a surface of the workpiece to represent a shape of an overlapping portion of the opening of the first optical slit and the opening of the second optical slit;
coupling and electrically connecting an interposer including the glass substrate and conductors provided in the respective through-holes and an integrated circuit chip to each other; and
coupling and electrically connecting the interposer and a circuit board to each other.
